(19) United States
(12) Patent Application Publication
(10) Pub. No.: US 2008/0008642 A1
(43) Pub. Date: Jan. 10, 2008

(54) Process For Producing Aluminum Nitride Crystal And Aluminum Nitride Crystal Obtained Thereby

(75) Inventors: Yusuke Mori, Osaka (JP); Takatamo Sasaki, Osaka (JP); Fumio Kawamura, Osaka (JP); Yoshimura Masashi, Osaka (JP); Minoru Kawahara, Osaka (JP); Hiroaki Isobe, Osaka (JP)

Correspondence Address: HAMRE, SCHUMANN, MUELLER & LARSON, P.C., P.O. BOX 2902, MINNEAPOLIS, MN, 55402-0902, US

(73) Assignees: OSAKA UNIVERSITY, OSAKA (JP); KANSAI TECHNOLOGY LICENSING, KYOTO (JP)

(21) Appl. No.: 11/661,013

(22) PCT Filed: Aug. 24, 2005
(86) PCT No.: PCT/JP05/15366

§ 371 Date: Feb. 21, 2007

(30) Foreign Application Priority Data
Aug. 24, 2004 (JP) 2004-243764

(51) Int. Cl. C01B 21/072; C30B 29/38; C30B 9/10

(52) U.S. Cl. 423/412; 117/4; 117/6

(57) ABSTRACT

The present invention provides a method for producing aluminum nitride crystals under mild pressure and temperature conditions. In the production method of aluminum nitride crystals, aluminum nitride crystals are formed and grown in the presence of nitrogen-containing gas by allowing aluminum and the nitrogen to react with each other in a flux containing the following component (A) and component (B), or a flux containing the following component (B). (A) At least one element selected from the group consisting of the alkali metal and the alkaline-earth metal. (B) At least one element selected from the group consisting of tin (Sn), gallium (Ga), indium (In), bismuth (Bi) and mercury (Hg).

### TECHNICAL FIELD

The present invention relates to methods for producing aluminum nitride crystals and aluminum nitride crystals obtained thereby.

### BACKGROUND ART

Group-III nitride semiconductors are used in the fields of, for example, hetero-junction high speed electron devices and photoelectron devices (such as semiconductor laser, light-emitting diodes, sensors, etc.), and such use is expected to spread further in the future. Of Group-III nitride semiconductors, aluminum nitride (AWN) has a significantly large band gap of approximately 6.3 eV, and has high insulation properties. For this reason, aluminum nitride crystals are used for, for example, a barrier layer when using gallium nitride (GaN) as a light-emitting device. On the other hand, a more efficient excitation light source, specifically, an ultraviolet light source having a wavelength shorter than the band gap wavelength of gallium nitride, has been desired. In response to this, in order to obtain excitation light with a high efficiency in an AlGaN semiconductor, a substrate having a high permeability (transparency) with respect to the wavelength of the excitation light is required. Since aluminum nitride crystals have a high permeability with respect to the wavelength of the excitation light, and also good thermal conductivity and alignment, it is suitable for the substrate. However, it has been practically impossible with conventional production methods to produce a high-quality aluminum nitride crystal of a large size that can serve as a substrate.

Since aluminum nitride has sublimation properties, single crystals thereof have been produced with a sublimation method. However, it has been impossible with the sublimation method to produce crystals of a bulk size that can be used as a substrate. Moreover, the obtained crystals included many dislocations, which caused unfavorable quality. As another method for producing aluminum nitride crystals, a method has been reported in which in a Ca₃N₂ flux, nitrogen and aluminum in the flux are allowed to react with each other to grow aluminum nitride crystals (see Non-Patent Document 1). However, in this method, the melting point of the Ca₃N₂ flux is as high as 1,200° C. and prevention of degradation further is required, so that a severe condition under a high temperature and a high pressure is required. In addition, due to the high corrosivity of the Ca₃N₂ flux, materials of equipment and apparatuses used, particularly materials to be used for a crucible, are limited. Therefore, this method has difficulties in its commercialization due to severely restricted production conditions.
Non-Patent Document 1: “THE SYNTHESIS OF ALUMINUM NITRIDE SINGLE CRYSTALS” Cortland O. Dugger (Mat. Res. Bull, Vol. 9, 331-336, 1974)

### DISCLOSURE OF INVENTION

Problem to be Solved by the Invention

The present invention was made in consideration of such situations. An object of the present invention is to provide a method for producing aluminum nitride crystals that makes it possible to produce aluminum nitride crystals of high quality and a large size under mild crystal production conditions, and aluminum nitride crystals obtained thereby.

Means for Solving Problem

In order to achieve the above-mentioned object, a method for producing aluminum nitride crystals of the present invention includes: forming and growing aluminum nitride crystals in the presence of nitrogen-containing gas by allowing aluminum and the nitrogen to react with each other in a flux containing the following component (A) and component (B), or a flux containing the following component (B).
(A) at least one element selected from the group consisting of the alkali metal and the alkaline-earth metal.
(B) at least one element selected from the group consisting of tin (Sn), gallium (Ga), indium (In), bismuth (Bi) and mercury (Hg).
   Effects of the Invention

As described above, a production method of the present invention is characterized by using a flux containing the component (A) and the component (B) or a flux containing the component (B) in liquid phase growth of aluminum nitride crystals using a flux. Accordingly, in the production method of present invention, the pressure and temperature applied for crystal growth can be lower than in conventional techniques so as to realize mild production conditions. A flux used in the present invention has lower corrosivity than those used in the conventional techniques, and therefore materials of equipment or apparatuses used in production have fewer restrictions than in conventional techniques. With a production method of the present invention, it is possible to obtain large aluminum nitride crystals of high quality and a bulk size, with fewer dislocations.

### BRIEF DESCRIPTION OF DRAWINGS

FIG. 1 is an optical micrograph of an aluminum nitride crystal obtained in an example of the present invention.

FIG. 2 is an electron micrograph of an aluminum nitride crystal obtained in another example of the present invention.

FIG. 3 is an electron micrograph of an aluminum nitride crystal obtained in still another example of the present invention.

FIG. 4 is an electron micrograph of an aluminum nitride crystal obtained in yet another example of the present invention.

FIG. 5 is an electron micrograph of an aluminum nitride crystal obtained in still another example of the present invention.

FIG. 6A is an electron micrograph of an aluminum nitride crystal obtained in yet another example of the present invention.

FIG. 6B is a graph showing a rocking curve of the aluminum nitride crystal of FIG. 6A.

FIG. 7 is an optical micrograph of an aluminum nitride crystal obtained in still another example of the present invention.

FIG. 8 is a graph showing XRD results of the aluminum nitride crystal of FIG. 7.

FIG. 9 is an optical micrograph of an aluminum nitride crystal obtained in yet another example of the present invention.

FIG. 10 is an electron micrograph of the cross section of the aluminum nitride crystal obtained by the example of FIG.9.

FIG. 11A is a cross-sectional view showing an exemplary configuration of a production apparatus used in a method for producing aluminum nitride crystals of the present invention.

FIG. 11B is a cross-sectional view showing another exemplary configuration of a production apparatus used in a method for producing aluminum nitride crystals of the present invention.

FIG. 12 is a cross-sectional view showing still another exemplary configuration of a production apparatus used in a method for producing aluminum nitride crystals of the present invention.

FIG. 13 is a cross-sectional view showing a rocking state of the configuration shown in FIG. 12.

FIG. 14 is a perspective view showing an exemplary reaction vessel used in a method for producing aluminum nitride crystals of the present invention.

### DESCRIPTION OF THE REFERENCE NUMERALS

1 pressure- and heat-resistant container

2 heating container

3 crusible (reaction vessel)

4 pipe

5 rocking device

6 shaft

7 nitrogen-containing gas

8 substrate

9 flux

10 reaction vessel (crucible)

10a, 10b projection

11 gas cylinder

13 pressure- and heat-resistant container

14 electric furnace

15 pressure controller

16 crusible

17 material

21, 22, 23 pipe

24, 25 valve

### DESCRIPTION OF THE INVENTION

Hereinafter, the present invention is described in further detail.

In the present invention, while action of the component (A) and the component (B) in the flux has not been made clear, the present inventors presume as follows. Alkali metals such as lithium (Li) or sodium (Na) reduce nitrogen (N) so that nitrogen can be dissolved easily in a flux containing aluminum (Al). Specifically, the alkali metals function as an agent for promoting dissolution of nitrogen (N) into the flux. Also, alkaline-earth metals such as Ca or Mg have a large binding energy with nitrogen (N), and thus serve to retain nitrogen (N) dissolved in the flux. In other words, the alkaline-earth metals function as an agent for retaining nitrogen (N) in the flux. The component (B) such as tin (Sn) functions as a mixing agent for preparing an alloy melt of flux components containing either or both of the alkali metal and the alkaline-earth metal, and aluminum, and further lowers the melting point of the whole flux containing aluminum (Al). Therefore, due to the action of the dissolution promoting agent, retaining agent and mixing agent, the nitrogen (N) concentration in the aluminum (Al)-containing flux can be increased, and in addition, the melting point of the whole system is lowered as a result of these metals being mixed together. As a result, effects such as improvement in yield and growth rate, and increase in transparency of obtained crystals can be achieved in a low-temperature growth as well. It should be noted that these actions of the component (A) and the components (B) are based on presumption, and are not essential to the mechanism of the present invention. The actions may have mechanisms other than the above-presumed mechanism, and thus the present invention is in no way bound by this presumption. Although it is preferable that the flux contains both of the alkali metal and the alkaline-earth metal, the flux may contain only one of, or neither of the alkali metal and the alkaline-earth metal.

In the present invention, the alkali metal is at least one metal selected from the group consisting of lithium (Li), sodium (Na), potassium (K), rubidium (Rb), cesium (Cs) and francium (Fr), and the alkaline-earth metal is at least one metal selected from the group consisting of calcium (Ca), magnesium (Mg), strontium (Sr), barium (Ba) and radium (Ra).

In the present invention, the component (A) preferably contains at least one element selected from the group consisting of lithium (Li), sodium (Na), calcium (Ca) and magnesium (Mg), and the component (B) preferably contains tin (Sn). In this case, the component (A) preferably contains at least one of lithium (Li) and sodium (Na), and at least one of calcium (Ca) and magnesium (Mg), and the component (B) preferably contains tin (Sn). Examples of the combination of the component (A) and the component (B) are described below. However, the present invention is not limited to the following combinations, and other combinations, for example, Li+In, may be employed. Of the following combinations, combinations of (4), (5) and (12) are preferable in terms of formation of uniform crystal film or the like. Also, in the present invention, a flux may contain the component (B) alone, e.g. a flux containing tin (Sn) alone.
(1) Na+Li+Mg+Ca+Sn
(2) Na+Mg+Ca+Sn
(3) Na+Mg++Sn
(4) Na+Ca+Sn
(5) Na+Sn
(6) Li+Mg+Ca+Sn
(7) Li+Mg+Sn
(8) Li+Ca+Sn
(9) Li+Sn
(10) Na+Li+Sn
(11) Mg+Ca+Sn
(12) Mg+Sn
(13) Ca+Sn

In the present invention, the flux may be made up of the component (A) and the component (B) alone, or the component (B) alone. However, the flux also may contain an other component.

In the present invention, although the mole ratio (Al/A+B) of the aluminum (Al) to the total of the component (A) and the component (B) is not particularly limited, the ratio may be in the range of, for example, 0.001 to 99.999, preferably 0.01 to 99.99, and more preferably 0.1 to 99.9.

In the present invention, although the mole ratio (A:B) between the component (A) and the component (B) is not particularly limited, the ratio may be in the range of, for example, 0.001:99.999 to 99.999:0.001, preferably 0.01:99.99 to 99.99:0.01, and more preferably 0.1:99.9 to 99.9:0.1.

In the present invention, although conditions of the reaction are not particularly limited, the temperature may be in the range of, for example, 300° C. to 2300° C., preferably 400° C. to 2000° C., and more preferably 500° C. to 1700° C., and the pressure may be in the range of, for example, 0.01 MPa to 1000 MPa, preferably 0.05 MPa to 100 MPa, and more preferably 0.1 MPa to 50 MPa.

In the flux, if the component (A) is magnesium (Mg) and the component (B) is tin (Sn), the reaction temperature preferably is 950° C. or higher.

In the present invention, the nitrogen-containing gas is, for instance, nitrogen (N₂) gas, ammonia (NH₃) gas or a mixed gas thereof, although there is no particular limitation on it.

In the present invention, it is preferable that a Group-III nitride is prepared in advance, and aluminum nitride crystals are grown using the Group-III nitride as seed crystal nuclei. In this case, it is preferable that a substrate with the Group-III nitride thin film formed on the surface thereof is prepared, with the thin film serving as seed crystal nuclei. Examples of the material to be used for the substrate include amorphous gallium nitride (GaN), amorphous aluminum nitride (AlN), sapphire (Al₂O₃), silicon (Si), gallium arsenic (GaAs), gallium nitride (GaN), aluminum nitride (AlN), silicon carbide (SiC), boron nitride (BN), lithium gallium oxide (LiGaO₂), zirconium boride (ZrB₂), zinc oxide (ZnO), various types of glass, various metals, boron phosphide (BP), MoS₂, LaAlO₃, NbN, MnFe₂O₄, ZnFe₂O₄, ZrN, TiN, gallium phosphide (GaP), MgAl₂O₄, NdGaO₃, LiAlO₂, ScAlMgO₄, Ca₈La₂(PO₄)₆O₂, etc. The thickness of the Group-III nitride thin film that serves as nuclei is not particularly limited, and may be in the range of, for instance, 0.0005 μm to 100000 μm, preferably 0.001 μm to 50000 μm, and more preferably 0.01 μm to 5000 μm. The thin film can be formed on the substrate by, for example, a metalorganic chemical vapor deposition method (a MOCVD method), a hydride vapor phase epitaxy (HVPE), a molecular beam epitaxy method (a MBE method), a sublimation method, etc. Since products in which a thin film of Group-III nitride has been formed on a substrate are commercially available, they may be used. The largest diameter of the thin film is, for instance, at least 2 cm, preferably at least 3 cm, and more preferably at least 5 cm. The larger the largest diameter, the more preferable the thin film. The upper limit thereof is not limited. However, since the standard for bulk compound semiconductors is two inches, from this viewpoint, the largest diameter preferably is 5 cm. In this case, the largest diameter is in the range of, for instance, 2 cm to 5 cm, preferably 3 cm to 5 cm, and more preferably 5 cm. In this specification, the “largest diameter” is the length of the longest line that extends between one point and another point on the periphery of the thin film surface. The Group-III nitride preferably is at least one of a crystal and an amorphous material, and more preferably aluminum nitride (AlN) crystals.

In this production method of the present invention using the seed crystal nuclei, there is a possibility that the seed crystal nuclei are dissolved by the flux before the nitrogen concentration in the flux rises. In order to prevent this from occurring, it is preferable that nitride be allowed to be present in the flux at least at an early stage of the reaction. Examples of the nitride include Ca₃N₂, Li₃N, NaN₃, BN, Si₃N₄, InN, etc. They may be used alone or in combination of two or more. Furthermore, the ratio of the nitride contained in the flux is, for instance, 0.0001 mole % to 99 mole %, preferably 0.001 mole % to 50 mole %, and more preferably 0.005 mole % to 10 mole %.

In the production method of the present invention, impurities may be present in the flux. In this case, aluminum nitride crystals containing impurities can be produced. Examples of the impurities include Si, Al₂O₃, In, InN, SiO₂, In₂O₃, Zn, Mg, ZnO, MgO, Ge, Ga, Be, Cd, Li, Ca, C and O.

In the present invention, it is preferable that single crystals are grown as the aluminum nitride crystals.

In the present invention, it is preferable that a heating container is disposed in a pressure-resistant container, a reaction vessel is placed in the heating container, a flux is prepared in the reaction vessel and the aluminum and nitrogen are allowed to react with each other to form and grow crystals in the flux. Use of such an apparatus having a double-container structure provides advantages such as more precise control of reaction conditions. The heating container may have pressure-resistant properties as well.

Next, aluminum nitride of the present invention is aluminum nitride crystals obtained by the production method of the present invention. Aluminum nitride crystals of the present invention are of high quality with few dislocations, and can be produced in a large bulk level size. For example, in the above-described method using a substrate with an aluminum nitride thin film formed on the surface thereof, it is possible to obtain aluminum nitride crystals having the largest diameter of 2 cm to 5 cm by using a substrate with a thin film having the largest diameter of 2 cm to 5 cm formed thereon. If the substrate is used, the thickness of the aluminum nitride crystals formed on the thin film can be adjusted by the crystal growth time. The longer the growth time, the larger the thickness is, and the thickness is, for example, 0.5 μm to 50 mm.

Next, a semiconductor apparatus of the present invention is a semiconductor apparatus that uses a nitride semiconductor, wherein the nitride semiconductor includes aluminum nitride crystals of the present invention.

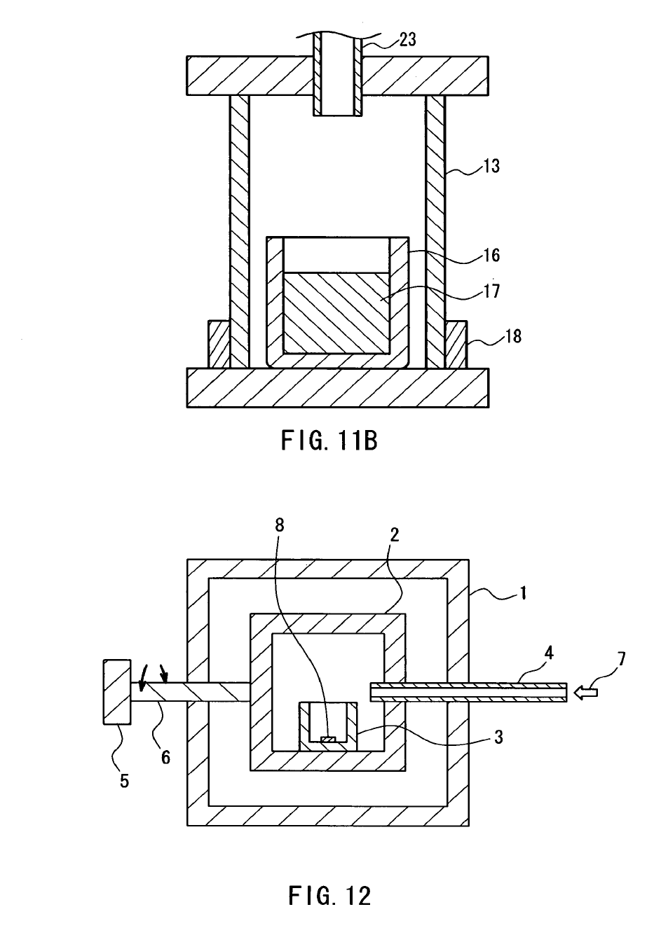

The production method of the present invention is implemented using the apparatuses shown in FIGS. 11A and 11B, for example. As shown in FIG. 11A, this apparatus includes a gas cylinder 11, an electric furnace 14, and a heat- and pressure-resistant container 13 placed in the electric furnace 14. A pipe 21 is connected to the gas cylinder 11 and is provided with a pressure controller 15 and a pressure control valve 25. A leak pipe is attached to somewhere on the pipe 21 and a leak valve 24 is disposed at the end of the leak pipe. The pipe 21 is connected to a pipe 22 that is connected to a pipe 23. The pipe 23 enters the electric furnace 14 and is connected to the heat- and pressure-resistant container 13. As shown in FIG. 11B, a crucible 16 is disposed in the heat- and pressure-resistant container 13, and flux components 17 have been put in the crucible 16. The flux components 17 contain the component (A) and the component (B), and Al as crystal material is contained therein. Examples of the material to be used for the crucible 16 include BN, AlN, rare-earth oxides, alkaline-earth metal oxides, W, SiC, graphite, diamond, diamond-like carbon, etc. Examples of the rare earths and alkaline-earth metals include Sc, Y, La, Ce, Pr, Nd, Pm, Sm, Eu, Gd, Tb, Dy, Ho, Er, Tm, Yb, Be, Mg, Ca, Sr, Ba, Ra. Among them, AlN, SiC, and diamond-like carbon are preferable because they tend not to dissolve in the flux. Furthermore, a crucible whose surface is coated with such a material also may be used.

Aluminum nitride crystals can be produced using the apparatus in a following manner, for example. Firstly, a crystal material (Al) and flux components (the components (A) and (B)) are put in the crucible 16. These material and components may be put concurrently or separately. The crucible 16 is placed in the heat- and pressure-resistant container 13. The heat- and pressure-resistant container 13 is disposed in the electric furnace 14 with an end of the pipe 23 connected thereto. In this state, nitrogen-containing gas is fed from the gas cylinder 11 to the heat- and pressure-resistant container 13 through the pipes 21, 22 and 23, and the heat- and pressure-resistant container 13 is heated with the electric furnace 14. The pressure in the heat- and pressure-resistant container 13 is adjusted with the pressure controller 15. By applying pressure and heat for a certain period of time, the material and components are melted, and Al and nitrogen are allowed to react with each other in the flux so as to form and grow crystals. After the crystals finish growing, obtained crystals are taken out from the crucible 16.

If the seed crystal nuclei are used to grow aluminum nitride crystals, for example, a substrate with a Group-III nitride thin film formed on the surface thereof is disposed in the crucible 16 in advance. In this state, crystals are grown in the flux as described above.

Next, in the production method of the present invention, the flux preferably is stirred to be mixed in the reaction vessel to grow the aluminum nitride crystals. The flux can be stirred to be mixed by, for instance, rocking the reaction vessel, rotating the reaction vessel, or a combination thereof. In addition, the flux also can be stirred to be mixed by, for instance, not only heating the reaction vessel for preparing the flux but also heating the lower part of the reaction vessel to generate heat convection. Furthermore, it may be stirred to be mixed using a stirring blade. These respective systems for stirring the flux to mix it can be combined with each other.

In the present invention, the manner of rocking the reaction vessel is not particular limited. For instance, the reaction vessel is rocked in a certain direction, wherein the reaction vessel is tilted in one direction and then is tilted in the opposite direction to the one direction. This rocking motion may be a regular motion or an intermittent irregular motion. Furthermore, a rotational motion may be employed in addition to the rocking motion. The tilt of the reaction vessel caused during the rocking also is not particularly limited. In the case of a regular rocking motion, the reaction vessel is rocked in a cycle of, for instance, 1 second to 10 hours, preferably 30 seconds to 1 hour, and more preferably 1 minute to 20 minutes. The maximum tilt angle of the reaction vessel during rocking with respect to the central line in the height direction of the reaction vessel is, for instance, 5 degrees to 70 degrees, preferably 10 degrees to 50 degrees, and more preferably 15 degrees to 45 degrees. Moreover, as described later, when a substrate is placed on the bottom of the reaction vessel, the reaction vessel may be rocked in the state where the thin film formed on the substrate is covered continuously with the flux or in the state where the flux does not cover the thin film of the substrate when the reaction vessel is tilted.

In the present invention, the reaction vessel may be a crucible.

In the production method of the present invention, the crystals preferably are grown, with the flux flowing, in a thin layer state, continuously or intermittently on the surface of the thin film formed on the substrate, by rocking the reaction vessel. When the flux is in a thin layer state, the nitrogen-containing gas dissolves easily in the flux. This allows a large amount of nitrogen to be supplied continuously to the growth faces of the crystals. Moreover, when the reaction vessel is rocked regularly in one direction, the flux flows regularly on the thin film, which allows the step flow of the growth faces of the crystals to be stable. This results in further uniform thickness and thus allows high quality crystals to be obtained.

In the production method of the present invention, it is preferable that before the crystals start growing, the reaction vessel be tilted in one direction to pool the flux on the bottom of the reaction vessel on the side to which the reaction vessel is tilted and thereby the flux prevented from coming into contact with the surface of the thin film of the substrate. In this case, the flux can be supplied onto the thin film of the substrate by rocking the reaction vessel after it is confirmed that the temperature of the flux has risen satisfactorily. As a result, formation of undesired compounds or the like are prevented and thus higher quality crystals can be obtained.

In the production method of the present invention, it is preferable that after the single crystals finish growing, the reaction vessel be tilted in one direction to remove the flux from the surface of the thin film of the substrate and to pool it on the bottom of the reaction vessel on the side to which the reaction vessel is tilted. In this case, when the internal temperature of the reaction vessel has decreased after the crystals finish growing, the flux does not come into contact with the aluminum nitride crystals that have been obtained. As a result, this can prevent any low quality crystals from growing on the crystals that have been obtained.

The manner of heating the reaction vessel for generating the heat convection is not particularly limited as long as it is carried out under conditions that allow heat convection to be generated. The position of the part of the reaction vessel to be heated is not particularly limited as long as it is a lower part of the reaction vessel. For instance, the bottom part or the side wall of the lower part of the reaction vessel may be heated. The temperature at which the reaction vessel is heated for generating the heat convection is, for instance, 0.01° C. to 500° C. higher than the heating temperature that is employed for preparing the flux, preferably 0.1° C. to 300° C. higher than that, more preferably 1° C. to 100° C. higher than that. A common heater can be used for the heating.

The manner of stirring the flux to mix it using the stirring blade is not particularly limited. For instance, it may be carried out through a rotational motion or a reciprocating motion of the stirring blade or a combination thereof. In addition, it may be carried out through a rotational motion or a reciprocating motion of the reaction vessel with respect to the stirring blade or a combination thereof. Furthermore, it may be carried out through a combination of the motion of the stirring blade itself and the motion of the reaction vessel itself. The stirring blade is not particularly limited. The shape and material to be employed for the stirring blade can be determined suitably according to, for instance, the size and shape of the reaction vessel. It, however, is preferable that the stirring blade be formed of a material that is free from nitrogen and has a melting point or a decomposition temperature of at least 2000° C. This is because when formed of such a material, the stirring blade is not melted by the flux and can prevent crystal nucleation from occurring on the surface of the stirring blade. Examples of the material to be used for the stirring blade include BN, AlN, rare-earth oxides, alkaline-earth metal oxides, W, SiC, graphite, diamond, diamond-like carbon, etc. A stirring blade formed of such a material also is not melted by the flux and can prevent crystal nucleation from occurring on the surface of the stirring blade, as in the case described above. Examples of the rare earths and the alkaline-earth metals include Sc, Y, La, Ce, Pr, Nd, Pm, Sm, Eu, Gd, Tb, Dy, Ho, Er, Tm, Yb, Be, Mg, Ca, Sr, Ba, and Ra. Preferable examples of materials to be used for the stirring blade include Y₂O₃, CaO, MgO, W, SiC, diamond, and diamond-like carbon. Among them, Y₂O₃ is the most preferable.

In the production method of the present invention, it is preferable that Al and a doping material be supplied to the flux while the crystals grow. This allows the crystals to grow continuously for a longer period of time. The method of supplying is not particularly limited but for example the following method may be employed. That is, a reaction vessel is formed of two parts including an inner part and an outer part and the outer part is divided into several small chambers. Each of the small chambers is provided with a door that can be opened and closed from the outside. A raw material to be supplied to the small chambers is put into the small chambers beforehand. When the door of a small chamber that is located on the higher side of the reaction vessel during rocking is opened, the raw material contained in the small chamber flows down to the inner reaction vessel by gravity and then is mixed. Further, when a small chamber of the outer part is empty, a first raw material that was used for growing crystals initially is removed and another raw material that is different from the first raw material and that has been put into a small chamber that is located in the opposite side is put into the inner reaction vessel, so that aluminum nitride crystals can be grown sequentially in which the ratio of Al and the type of the doping material are varied. Changing the direction of rocking (for instance, employing both the rocking motion and the rotational motion) makes it possible to increase the number of small chambers of the outer part that can be used and to make many raw materials containing various compositions and impurities available.

In the production method of the present invention, it is preferable that the flux be stirred to be mixed in an atmosphere of inert gas other than nitrogen first and then in an atmosphere of the nitrogen-containing gas that is obtained by substituting the inert gas with the nitrogen-containing gas. That is, there is a possibility that the flux and the Group III element have not been mixed well in the early stage of stirring the flux to mix it, and in this case, there is a possibility that the flux components react with nitrogen to form nitride. The production of nitride can be prevented when the nitrogen-containing gas is not present. In the unpressurized state, however, there is a possibility that the high temperature flux and Group III element evaporate. In order to solve this problem, it is preferable that in the early stage of stirring the flux to mix it, it be stirred to be mixed in an atmosphere of inert gas other than nitrogen, and then the stirring be continued, with the inert gas being substituted by the nitrogen-containing gas, as described above. In this case, it is preferable that the substitution be carried out gradually. The inert gas to be used herein can be argon gas or helium gas, for instance.

The apparatus of the present invention is used in the method for producing aluminum nitride crystals by rocking a reaction vessel containing the flux. The apparatus includes: means for heating the reaction vessel for preparing the flux by heating the flux materials in the reaction vessel; means for feeding nitrogen-containing gas to be used for reacting aluminum (Al) contained in the flux and nitrogen with each other by feeding the nitrogen-containing gas into the reaction vessel; and means for rocking the reaction vessel in a certain direction by tilting the reaction vessel in one direction and then tilting it in the opposite direction to the one direction. Preferably, the apparatus is provided with means for rotating the reaction vessel in addition to or instead of the rocking means. Materials of the flux are, for example, the component (A) and the component (B).

An example of the apparatus of the present invention is shown with the cross-sectional view in FIG. 12. As shown in FIG. 12, this apparatus has a double-container structure in which a heating container 2 is disposed in a heat- and pressure-resistant container 1. A pipe 4 for feeding nitrogen-containing gas 7 is connected to the heating container 2. In addition, a shaft 6 that extends from a rocking device 5 also is connected to the heating container 2. The rocking device 5 is composed of a motor, a mechanism for controlling the rotation thereof, etc. An example of the method for producing aluminum nitride of the present invention using this apparatus is described below.

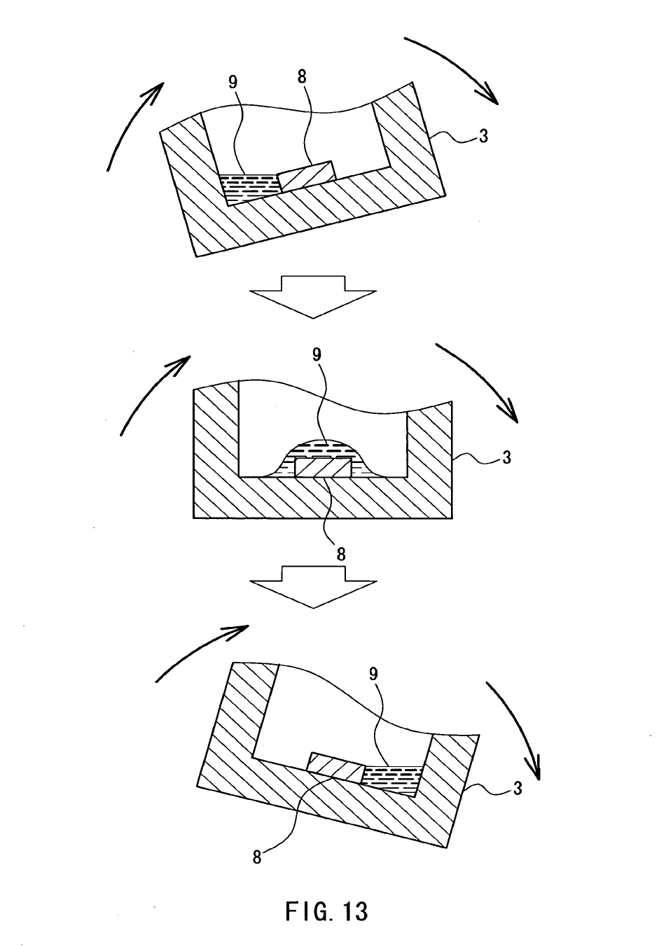

First, a substrate 8 with an aluminum nitride thin film formed on the surface thereof is placed on the bottom of a reaction vessel 3. Then the component (A) and the component (B) to be used as flux materials and aluminum (Al) are put into the reaction vessel 3. This reaction vessel 3 then is placed in the heating container 2. Thereafter, the heating container 2 as a whole is tilted with the rocking device 5 and the shaft 6, so that the surface of the thin film formed on the substrate 8 is prevented from being in contact with aluminum, the flux materials, etc. In this state, heating is started. After the temperature becomes sufficiently high and thereby the flux is brought into a preferable state, the whole heating container 2 is rocked by the rocking device 5 and thereby the reaction vessel is rocked. An example of the flow of the flux caused by this rocking is shown in FIG. 13. In FIG. 13, the same parts as those shown in FIG. 12 are indicated with the same numerals. As shown in FIG. 13, in the reaction vessel 3 tilted to the left, the flux 9 pools on the left side on the bottom of the reaction vessel 3 and therefore is not in contact with the surface of the substrate 8. As indicated with an arrow, when the reaction vessel 3 is stood upright, the flux 9 covers the surface of the substrate 8, in a thin-film state. Further, when the reaction vessel 3 is tilted to the right, the flux 9 flows to be pooled on the right side on the bottom of the reaction vessel 3, which prevents the flux 9 from coming into contact with the surface of the substrate 8. When this motion is carried out so as to tilt the reaction vessel 3 from the right to the left, the flux 9 flows in the opposite direction to the above-mentioned direction. During this rocking, when nitrogen-containing gas 7 is fed into the heating container 2 and the reaction vessel 3 through the pipe 4, the aluminum and nitrogen react with each other in the flux 9 to form aluminum nitride crystals on the surface of the thin film of the substrate 8. In this case, feeding of the nitrogen-containing gas may be started before the rocking motion starts or may be started after the rocking motion starts as described above. When crystal growth is completed, the reaction vessel 3 is brought into a tilted state to prevent the flux 9 from coming into contact with the aluminum nitride crystals newly obtained on the substrate 8. Then after the internal temperature of the heating container 2 has fallen, the aluminum nitride crystals are collected without being separated from the substrate 8. In this example, the substrate was placed on the center of the bottom of the reaction vessel. The present invention, however, is not limited thereto and the substrate may be placed in a place that is spaced from the center.

The material to be used for the reaction vessel that is employed in the production method of the present invention is not particularly limited. Examples of the material include BN, AlN, rare-earth oxides, alkaline-earth metal oxides, W, SiC, graphite, diamond, diamond-like carbon, etc. Examples of the rare earth and the alkaline-earth metal include Sc, Y, La, Ce, Pr, Nd, Pm, Sm, Eu, Gd, Tb, Dy, Ho, Er, Tm, Yb, Be, Mg, Ca, Sr, Ba, and Ra. Among them, AlN, SiC and the diamond-like carbon are preferable because they tend not to dissolve in the flux. Furthermore, a reaction vessel whose surface is coated with such a material also may be used.

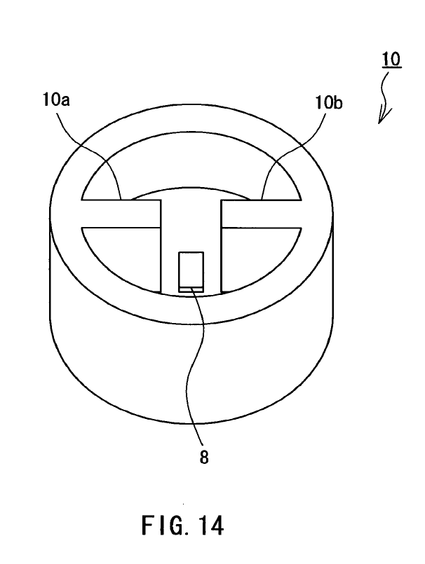

In addition, the shape of the reaction vessel (or the crucible) to be used in the production method of the present invention also is not particularly limited. It, however, is preferable that the reaction vessel has a cylindrical shape and includes two projections that protrude from the inner wall thereof toward the circular center, and a substrate placed between the two projections. Such a shape allows the flux to flow concentrating on the surface of the substrate placed between the two projections when the reaction vessel is rocked. An example of this reaction vessel is shown in FIG. 14. As shown in FIG. 14, this reaction vessel 10 has a cylindrical shape and includes two wall-like projections 10a and 10b that protrude toward the circular center. A substrate 8 is placed between the projections 10a and 10b. The conditions for using the reaction vessel with such a shape are not limited except that the reaction vessel is rocked in the direction perpendicular to the direction in which the two projections protrude.

Next, examples of the present invention are described.

### EXAMPLE 1

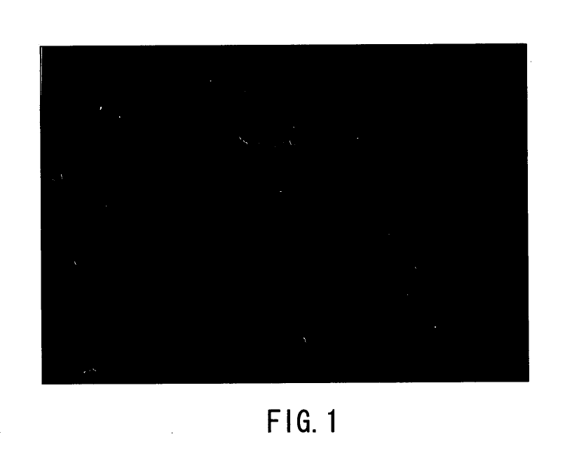

Aluminum nitride crystals were produced as described above, using the apparatuses shown in FIGS. 11A and 11B. Specifically, Al (raw material of crystal), Li (the component (A)) and In (the component (B)) were put in a BN crucible, and melted by applying heat and pressure under the conditions described below in an atmosphere of nitrogen (N₂) gas so as to grow aluminum nitride crystals. Then, the obtained product was identified as the aluminum nitride crystal with an optical microscope and through X-ray diffraction measurement (XRD measurement). The optical micrograph (magnification: 100 times) of FIG. 1 shows the obtained aluminum nitride crystal (grown at Li:In=75:25).

(Production condition)

Growth temperature: 800° C.

Growth pressure: 30 atm (3.04 MPa)

Growth time: 96 hours

Crucible used: BN crucible (inner diameter of 9 mm)

Gas used: N₂ gas

Al: 0.2 g

Al:flux (mole ratio)=3:7

Li:In (mole ratio)=50:50 and 75:25

### EXAMPLE 2

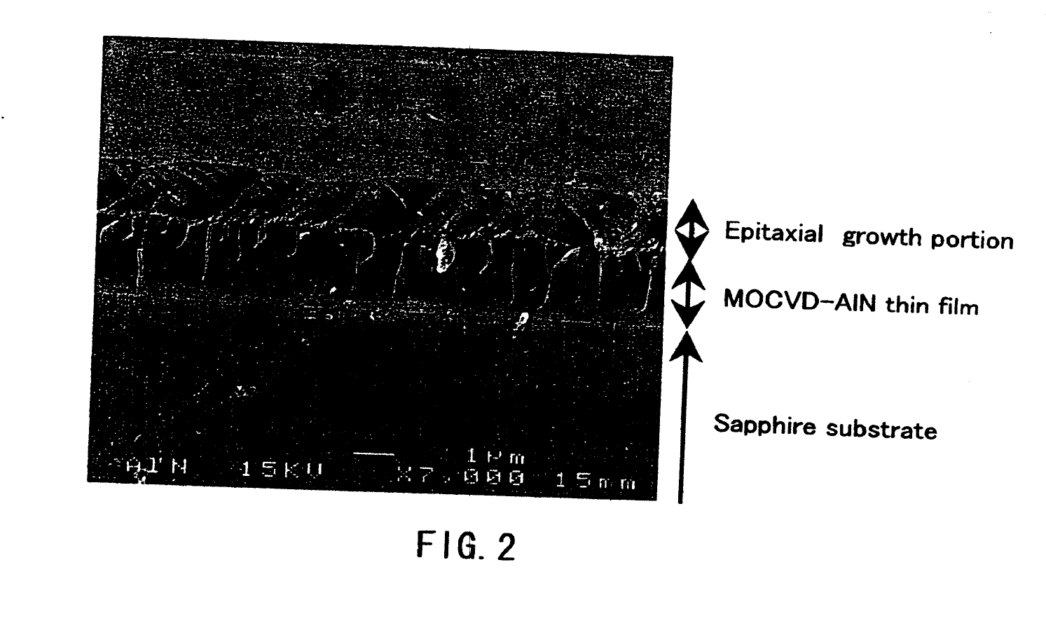

Aluminum nitride crystals were produced on a substrate disposed in a crucible using the apparatuses shown in FIGS. 11A and 11B. Specifically, Al (raw material of crystal), Na and Ca (the component (A)) and Sn (the component (B)) were put in a crucible having a substrate disposed therein, and melted by applying heat and pressure under the conditions described below in an atmosphere of nitrogen (N₂) gas so as to grow aluminum nitride crystals. Then, the obtained product was identified as the aluminum nitride crystal with a scanning electron microscope (SEM) and through X-ray diffraction measurement (XRD measurement). The scanning electron micrograph (magnification: 7,000 times) of FIG. 2 shows the obtained aluminum nitride crystal. As shown in the micrograph of FIG. 2, in this example, it was observed that a transparent and flat thin film of aluminum nitride crystal with a thickness of approximately 1 μm had grown on a MOCVD-AlN thin film substrate. Note that “sapphire substrate” in FIG. 2 indicates a sapphire substrate portion of the substrate, “MOCVD-AlN thin film” indicates an AlN thin film portion of the substrate and “epitaxial growth portion” indicates aluminum nitride crystals formed on the substrate.

(Production condition)

Growth temperature: 890° C.

Growth pressure: 25 atm (2.53 MPa)

Growth time: 96 hours

Substrate: obtained by forming an AlN thin film (10×10 mm) on a sapphire substrate by MOCVD method

Crucible used: Al₂O₃ crucible

Gas used: N₂ gas

Composition charged: Na: 0.95 g, Ca: 0.03 g, Sn: 2.12 g, Al: 0.40 g (Na:Ca:Sn:Al=20:55:1:24 (mol %))

### EXAMPLE 3

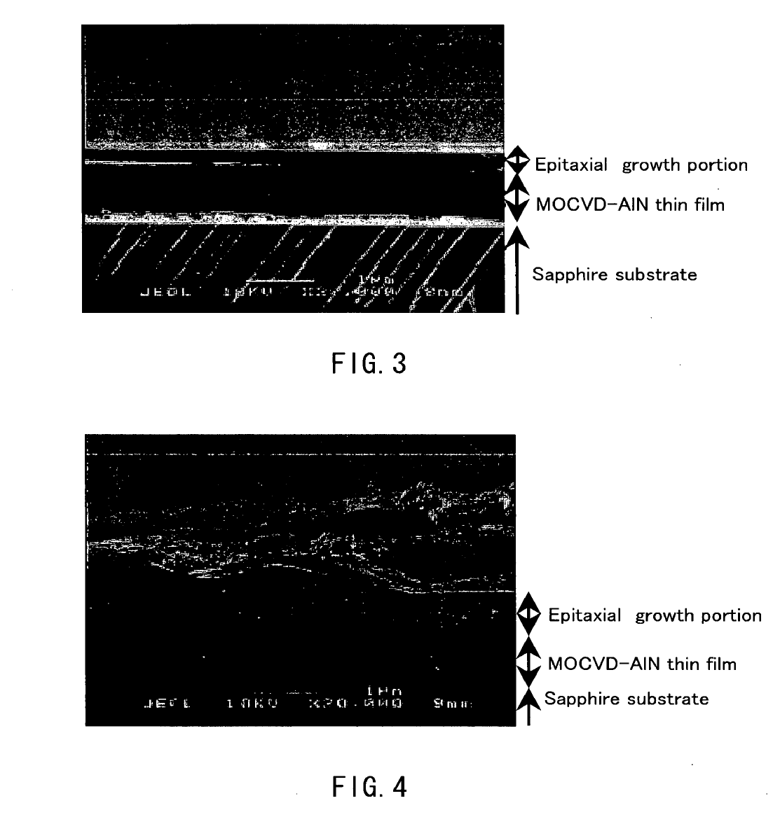

Aluminum nitride crystals were produced on a substrate disposed in a crucible using the apparatuses shown in FIGS. 11A and 11B. Specifically, Al (raw material of crystal) and Sn (the component (B)) were put in a crucible having a substrate disposed therein, and melted by applying heat and pressure under the conditions described below in an atmosphere of nitrogen (N₂) gas so as to grow aluminum nitride crystals. Then, the obtained product was identified as the aluminum nitride crystal with a scanning electron microscope (SEM) and through X-ray diffraction measurement (XRD measurement). The scanning electron micrograph (magnification: 20,000 times) of FIG. 3 shows the obtained aluminum nitride crystal. As shown in the micrograph of FIG. 3, in this example, it was observed that a transparent and flat thin film of aluminum nitride crystal with a thickness of approximately 200 nm had grown on a MOCVD-AlN thin film substrate. Note that “sapphire substrate” in FIG. 3 indicates a sapphire substrate portion of the substrate, “MOCVD-AlN thin film” indicates an AlN thin film portion of the substrate and “epitaxial growth portion” indicates aluminum nitride crystals formed on the substrate.

(Production condition)

Growth temperature: 900° C.

Growth pressure: 10 atm (1.04 MPa)

Growth time: 96 hours

Substrate: obtained by forming an AlN thin film (10×10 mm) on a sapphire substrate by MOCVD method

Crucible used: Al₂O₃ crucible

Gas used: N₂ gas

Composition charged: Sn:Al (mole ratio)=3:1

### EXAMPLE 4

Aluminum nitride crystals were produced on a substrate disposed in a crucible using the apparatuses shown in FIGS. 11A and 11B. Specifically, Al (raw material of crystal) and Sn (the component (B)) were put in a crucible having a substrate disposed therein, and melted by applying heat and pressure under the conditions described below in an atmosphere of nitrogen (N₂) gas so as to grow aluminum nitride crystals. Then, the obtained product was identified as the aluminum nitride crystal with a scanning electron microscope (SEM) and through X-ray diffraction measurement (XRD measurement). The scanning electron micrograph (magnification: 20,000 times) of FIG. 4 shows the obtained aluminum nitride crystal. As shown in the micrograph of FIG. 4, in this example, it was observed that a thin film of aluminum nitride crystal with a thickness of approximately 1 μm or more had grown on a MOCVD-AlN thin film substrate. Note that “sapphire substrate” in FIG. 4 indicates a sapphire substrate portion of the substrate, “MOCVD-AlN thin film” indicates an AlN thin film portion of the substrate and “epitaxial growth portion” indicates aluminum nitride crystals formed on the substrate.

(Production condition)

Growth temperature: 900° C.

Growth pressure: 10 atm (1.04 MPa)

Growth time: 96 hours

Substrate: obtained by forming an AlN thin film (10×10 mm) on a sapphire substrate by MOCVD method

Crucible used: Al₂O₃ crucible

Gas used: N₂ gas

Composition charged: Sn:Al (mole ratio)=1:3

### EXAMPLE 5

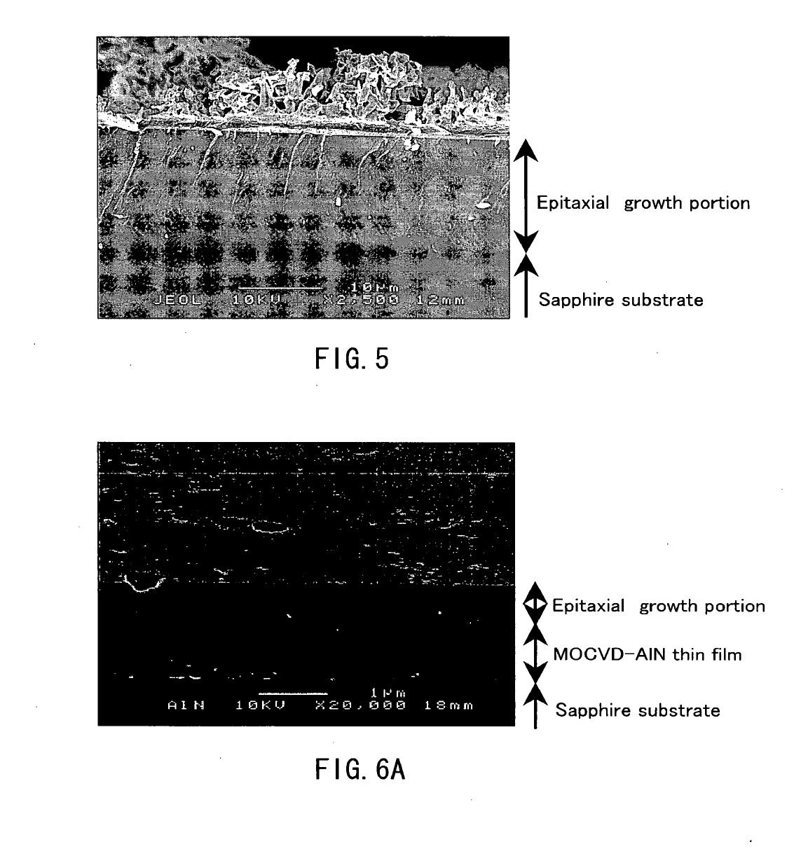

Except that Li was used as the component (A) and Sn as the component (B), aluminum nitride crystals were produced using the apparatuses shown in FIGS. 11A and 11B in a similar manner to Example 2. Specifically, Al (raw material of crystal), Li (the component (A)) and Sn (the component (B)) were put in a crucible, and melted by applying heat and pressure under the conditions described below in an atmosphere of nitrogen (N₂) gas so as to grow aluminum nitride crystals on the substrate. Then, the obtained product was identified as the aluminum nitride crystal with a scanning electron microscope (SEM) and through X-ray diffraction measurement (XRD measurement). The scanning electron micrograph (magnification: 2,500 times) of FIG. 5 shows the obtained aluminum nitride crystal. “Sapphire substrate” in FIG. 5 indicates the substrate, indicates an AlN thin film portion of the substrate and “epitaxial growth portion” indicates aluminum nitride crystals formed on the substrate. Note that it is difficult to recognize an AlN thin film on the substrate due to a low magnification in FIG. 5.

(Production condition)

Growth temperature: 980° C.

Growth pressure: 3 atm (0.304 MPa)

Growth time: 66 hours

Substrate: obtained by forming an AlN thin film (10×10 mm) on a sapphire substrate by MOCVD method

Crucible used: Al₂O₃ crucible

Gas used: N₂ gas

Composition charged: Li: 0.003 g, Sn: 2.59 g, Al: 0.40 g (Li:Sn:Al=1:59:40 (mol %))

### EXAMPLE 6

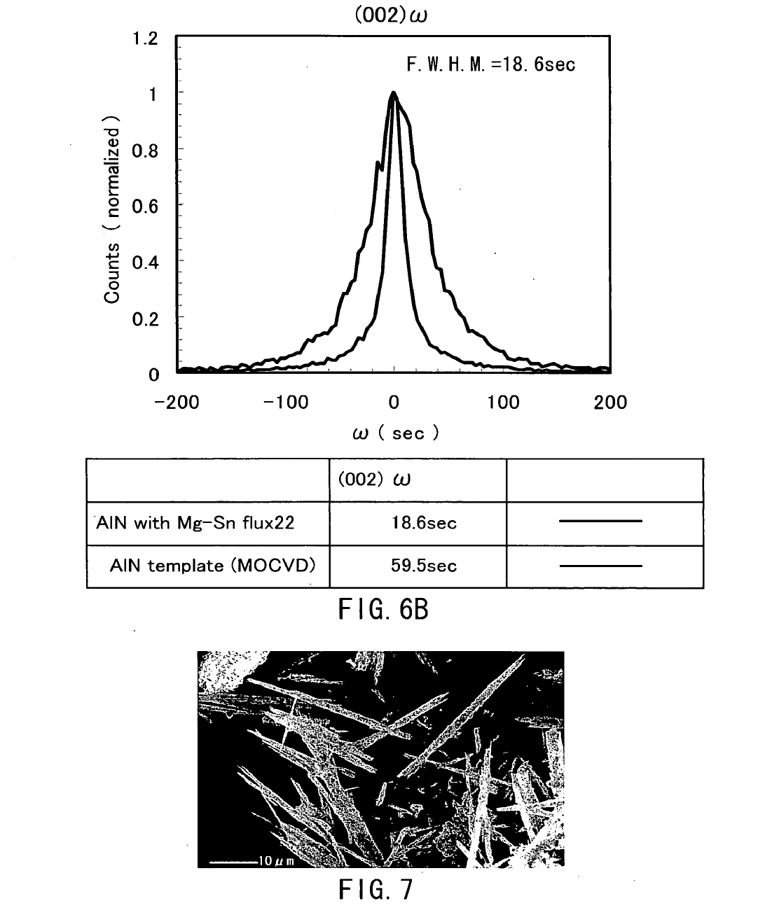

Except that Mg was used as the component (A) and Sn as the component (B), aluminum nitride crystals were produced using the apparatuses shown in FIGS. 11A and 11B in a similar manner to Example 2. Specifically, Al (raw material of crystal), Mg (the component (A)) and Sn (the component (B)) were put in a crucible, and melted by applying heat and pressure under the conditions described below in an atmosphere of nitrogen (N₂) gas so as to grow aluminum nitride crystals on the substrate. Then, the obtained product was identified as the aluminum nitride crystal with a scanning electron microscope and through X-ray diffraction measurement (XRD measurement). The scanning electron micrograph (magnification: 20,000 times) of FIG. 6A shows the obtained aluminum nitride crystal. “Sapphire substrate” in FIG. 6A indicates a sapphire substrate portion of the substrate, “MOCVD-AlN thin film” indicates an AlN thin film portion of the substrate and “epitaxial growth portion” indicates aluminum nitride crystals formed on the substrate. As shown in the micrograph of FIG. 6A, it was observed that a transparent and flat thin film of aluminum nitride crystal with a thickness of approximately 0.5 μm had grown on a MOCVD-AlN thin film substrate. Furthermore, as shown in the graph of FIG. 6B, the rocking curve measurement shows that the full-width at half-maximum of aluminum nitride crystal due to epitaxial growth was 18.6 seconds, and it was understood that the crystallinity had improved greatly compared with approximately 100 seconds for the underlying AlN thin film.

(Production condition)

Growth temperature: 950° C.

Growth pressure: 5 atm (0.507 MPa)

Growth time: 96 hours

Substrate: obtained by forming an AlN thin film (5×10 mm) on a sapphire substrate by MOCVD method

Crucible used: Al₂O₃ crucible

Gas used: N₂ gas

Composition charged: Mg: 0.013 g, Sn: 2.14 g, Al: 0.50 g (Mg:Sn:Al=1.5:48.5:50 (mol %))

### EXAMPLE 7

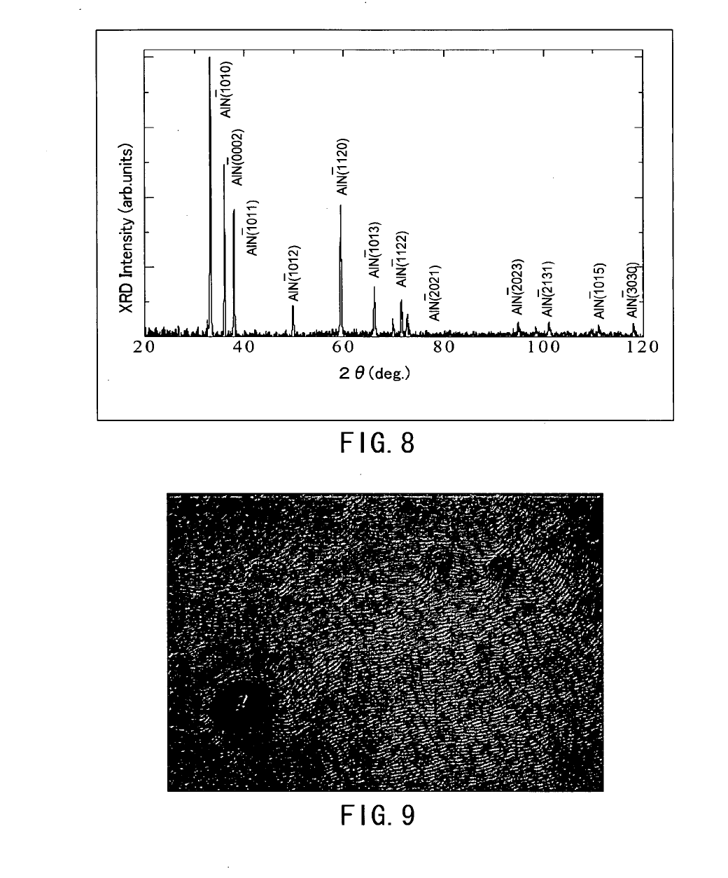

Aluminum nitride crystals were produced in a similar manner to Example 1, using the apparatuses shown in FIGS. 11A and 11B. Specifically, Al (raw material of crystal), Ca (the component (A)) and Sn (the component (B)) were put in a BN crucible, and melted by applying heat and pressure under the conditions described below in an atmosphere of nitrogen (N₂) gas so as to grow aluminum nitride crystals. Then, the obtained product was identified as the aluminum nitride crystal with an optical microscope and through X-ray diffraction measurement (XRD measurement). The optical micrograph (magnification: 1,000 times) of FIG. 7 shows the obtained aluminum nitride crystal. The graph in FIG. 8 shows the X-ray diffraction measurement results.

(Production condition)

Growth temperature: 900° C.

Growth pressure: 30 atm (3.04 MPa)

Growth time: 48 hours

Crucible used: BN crucible (inner diameter of 9 mm)

Gas used: N₂ gas

Al: 0.15 g

Al:flux (mole ratio)=7:3

Ca:Sn (mole ratio)=2:8

### EXAMPLE 8

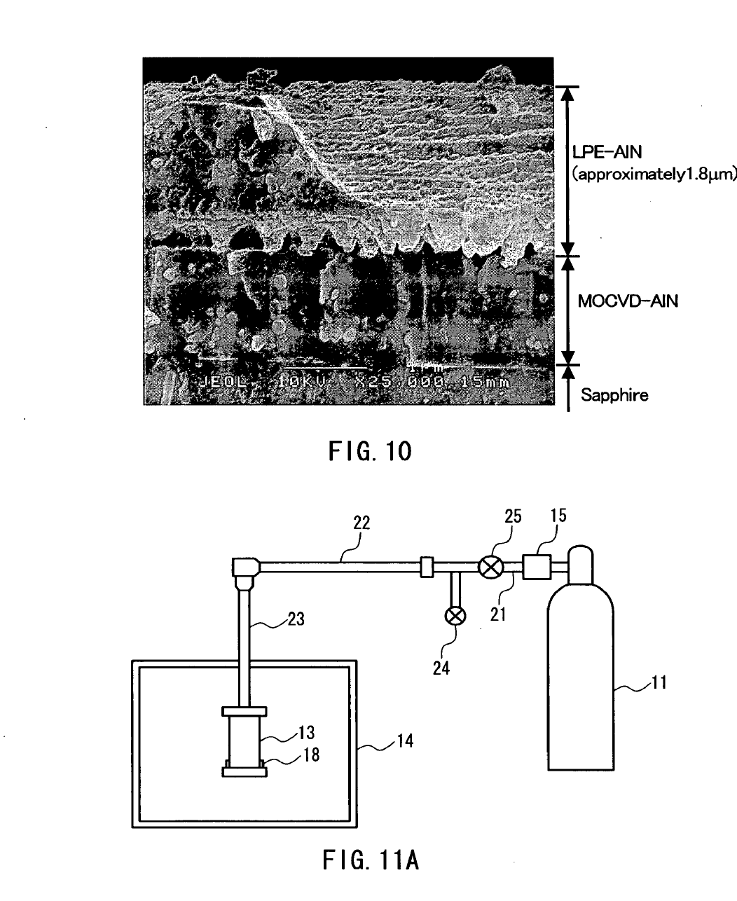

Aluminum nitride crystals were produced as described above, using the apparatuses shown in FIGS. 11A and 11B as well as a sapphire substrate with an aluminum nitride thin film formed on the surface thereof. Specifically, the substrate (10×10 mm), Al, Ca (the component (A)) and Sn (the component (B)) were put in an alumina crucible, and melted by applying heat and pressure under the conditions described below in an atmosphere of nitrogen (N₂) gas so as to grow aluminum nitride crystals. The aluminum nitride crystal thin film on the substrate was formed by MOCVD method. Then, the obtained aluminum nitride crystals were evaluated with an optical microscope and a scanning electron microscope (SEM). The optical micrograph (magnification: 200 times) of FIG. 9 shows the surface of the obtained aluminum nitride crystals, and the SEM micrograph (magnification: 25,000 times) of FIG. 10 shows the cross section of the crystals. As shown in the optical micrograph of FIG. 9, stripes are present on the crystal surface, which indicates that the crystals were grown in a liquid phase. As shown in the SEM micrograph of FIG. 10, aluminum nitride crystals having a thickness of approximately 1.8 μm were obtained. Note that “sapphire” in FIG. 10 indicates the sapphire substrate, “MOCVD-AlN” indicates an aluminum nitride thin film on the substrate and “LPE-AlN” indicates aluminum nitride crystals formed in the flux.

(Production condition)

Growth temperature: 900° C.

Growth pressure: 5 atm (0.507 MPa)

Growth time: 96 hours

Crucible used: alumina crucible (inner diameter of 9 mm)

Gas used: N₂ gas

Al: 0.15 g

Al:flux (mole ratio)=3:7

Ca:Sn (mole ratio)=2:8

### INDUSTRIAL APPLICABILITY

As described above, with the production method of the present invention, aluminum nitride crystals of high quality and a large size can be produced under mild pressure and temperature conditions. Aluminum nitride crystals obtained by the present invention can be used, for example, as semiconductors, and in particular, suitably used for a substrate for a light-emitting device. The aluminum nitride crystals can be used also in other applications.

1. A method for producing aluminum nitride crystals, wherein aluminum nitride crystals are formed and grown in the presence of nitrogen-containing gas by allowing aluminum and the nitrogen to react with each other in a flux containing component (B) below:
(B) at least one element selected from the group consisting of tin (Sn), gallium (Ga), indium (In), bismuth (Bi) and mercury (Hg).

2. The production method according to claim 41, wherein the alkali metal is at least one metal selected from the group consisting of lithium (Li), sodium (Na), potassium (K), rubidium (Rb), cesium (Cs) and francium (Fr), and the alkaline-earth metal is at least one metal selected from the group consisting of calcium (Ca), magnesium (Mg), strontium (Sr), barium (Ba) and radium (Ra).

3. The production method according to claim 41,
wherein the component (A) contains at least one element selected from the group consisting of lithium (Li), sodium (Na), calcium (Ca) and magnesium (Mg), and
the component (B) contains tin (Sn).

4. The production method according to claim 41,
wherein the component (A) contains at least one of lithium (Li) and sodium (Na), and at least one of calcium (Ca) and magnesium (Mg), and
the component (B) contains tin (Sn).

5. The production method according to claim 41, wherein a mole ratio (Al/A+B) of aluminum (Al) to the total of the component (A) and the component (B) is in a range from 0.001 to 99.999.

6. The production method according to claim 41, wherein a mole ratio between the component (A) and the component (B) (A:B) is in a range from 0.001:99.999 to 99.999:0.001.

7. The production method according to claim 1, wherein the reaction is carried out at a temperature from 300° C. to 2300° C. under a pressure of 0.01 MPa to 1000 MPa.

8. The production method according to claim 1, wherein the nitrogen-containing gas is at least one selected from the group consisting of nitrogen (N₂) gas, ammonia (NH₃) gas and a mixed gas thereof.

9. The production method according to claim 1, wherein a Group-III nitride is prepared in advance, and aluminum nitride crystals are grown using the Group-III nitride as a seed crystal nucleus.

10. The production method according to claim 9, wherein a substrate with a Group-III nitride thin film formed on the surface thereof is prepared, with the thin film serving as the seed crystal nucleus.

11. The production method according to claim 9, wherein the Group-III nitride is at least one of a crystal and an amorphous material.

12. The production method according to claim 9, wherein the Group-III nitride is aluminum nitride (AlN) crystals.

13. The production method according to claim 1, wherein prior to the reaction, a nitride is allowed to be present in the flux.

14. The production method according to claim 13, wherein the nitride is at least one selected from the group consisting of Ca₃N₂, Li₃N, NaN₃, BN, Si₃N₄ and InN.

15. The production method according to claim 1, wherein impurities are allowed to be present in the flux.

16. The production method according to claim 15, wherein the impurities are at least one selected from the group consisting of Si, Al₂O₃, In, InN, SiO₂, In₂O₃, Zn, Mg, ZnO, MgO, Ge, Ga, Be, Cd, Li. Ca, C and O.

17. The production method according to claim 1, wherein the aluminum nitride crystal is a single crystal.

18. The production method according to claim 1, wherein the aluminum nitride crystals are grown, with the flux having been stirred to be mixed in the reaction vessel.

19. The production method according to claim 18, wherein the reaction vessel is rocked and thereby the flux is stirred to be mixed.

20. The production method according to claim 18, wherein the reaction vessel is rotated, or rotated and rocked, and thereby the flux is stirred to be mixed.

21. The production method according to claim 18, wherein the substrate according to claim 10 is placed in the reaction vessel, and crystals are grown on a thin film of the substrate.

22. The production method according to claim 21, wherein the crystals are grown with the flux flowing continuously or intermittently in a thin layer state on a surface of the thin film formed on the substrate.

23. The production method according to claim 19, wherein before the crystals start growing, the reaction vessel is tilted in one direction, so that a the flux is pooled on a bottom of the reaction vessel on a side to which the reaction vessel is tilted and thereby the flux is prevented from coming into contact with a surface of the thin film of the substrate.

24. The production method according to claim 19, wherein after the crystals finish growing, the reaction vessel is tilted in one direction, so that the flux is removed from a surface of the thin film of the substrate and is pooled on the bottom of the reaction vessel on a side to which the reaction vessel is tilted.

25. The production method according to claim 18, wherein the flux is stirred to be mixed by heating a lower part of the reaction vessel to generate heat convection.

26. The production method according to claim 1, wherein aluminum (Al) is supplied to the flux while the crystals grow.

27. The production method according to claim 18, wherein the flux is stirred to be mixed in an atmosphere of inert gas other than nitrogen first and then in an atmosphere of the nitrogen-containing gas that is obtained by substituting the inert gas with the nitrogen-containing gas.

28. The production method according to claim 27, wherein the inert gas is substituted with the nitrogen-containing gas gradually.

29. The production method according to claim 18, wherein the flux is stirred to be mixed using a stirring blade.

30. The production method according to claim 29, wherein the flux is stirred to be mixed using the stirring blade, which is carried out through a rotational motion or a reciprocating motion of the stirring blade or a combination thereof.

31. The production method according to claim 29, wherein the flux is stirred to be mixed using the stirring blade, which is carried out through a rotational motion or a reciprocating motion of the reaction vessel with respect to the stirring blade or a combination thereof.

32. The production method according to claim 29, wherein the stirring blade is formed of a material that is free from nitrogen and has a melting point of at least 2000° C.

33. The production method according to claim 32, wherein the material is at least one material selected from the group consisting of Y₂O₃, CaO, MgO, and W.

34. The production method according to claim 32, wherein the material is Y₂O₃.

35. The production method according to claim 18, wherein the reaction vessel is a crucible.

36. The production method according to claim 1, wherein a heating container is disposed in a pressure-resistant container and a reaction vessel is placed in the heating container, the flux is prepared in the reaction vessel, and the aluminum and the nitrogen are allowed to react with each other to form and grow crystals in the flux.

37. (canceled)

38. (canceled)

39. Aluminum nitride crystals obtained by the production method according to claim 1.

40. A semiconductor apparatus using a nitride semiconductor, wherein the nitride semiconductor includes the aluminum nitride crystal of claim 39.

41. The production method according to claim 1, wherein the flux further contains component (A) below:
(A) at least one element selected from the group consisting of the alkali metal and the alkaline-earth metal.
